(19) United States
(12) Patent Application Publication
(10) Pub. No.: US 2026/0062284 A1
(43) Pub. Date: Mar. 5, 2026

(54) Transducer

(71) Applicant: SEIKO EPSON CORPORATION, Tokyo (JP)

(72) Inventors: Teruo TAKIZAWA, Matsumoto (JP); Shota KIGURE, Matsumoto (JP)

(21) Appl. No.: 19/312,787

(22) Filed: Aug. 28, 2025

(30) Foreign Application Priority Data
Aug. 29, 2024 (JP) 2024-147338

(51) Int. Cl. B81B 7/00; B81B 3/00; B81C 1/00; G01P 15/125; G01P 15/18

(52) U.S. Cl. CPC B81B 7/0038; B81B 3/0051; B81C 1/00285; G01P 15/125; G01P 15/18; B81B 2201/0235; B81B 2203/0136; B81B 2203/04; B81C 2203/0109; B81C 2203/019

(57) ABSTRACT

A transducer includes a first substrate; a second substrate that is disposed to overlap the first substrate and is provided with an insulating layer on a surface of the second substrate; a functional element provided between the first substrate and the second substrate; and a metal eutectic layer that bonds the first substrate and the second substrate to each other in a bonding region positioned around the functional element, in which a recess is provided in a first surface of the second substrate on the first substrate side, the recess is configured with a second surface that is a bottom, and a side wall that connects the first surface and the second surface, the insulating layer includes a first portion provided on the first surface, a second portion provided on the side wall, and a third portion provided on the second surface, and the bonding region is disposed between the second portions when viewed in plan in a Y axis direction along a Y axis.

The present application is based on, and claims priority from JP Application Serial Number 2024-147338, filed Aug. 29, 2024, the disclosure of which is hereby incorporated by reference herein in its entirety.

### BACKGROUND

### 1. Technical Field

The present disclosure relates to a transducer.

### 2. Related Art

In the related art, a sensor device including a base body having a cavity, a sensor element suspended in the cavity, and a lid that seals the cavity is known. The base body and the lid were bonded to each other via a bonding material. The bonding material was required to have high bonding strength and high long-term reliability of sealing.

For example, US 2010/0059835 discloses an inertial sensor using an AlGe eutectic as a bonding material. According to the document, the concentration of Ge in the AlGe eutectic is assumed to be uniform or a function of the distance from the lid or the base body. In particular, when the heat treatment is performed for a long time, it is disclosed that the concentration of Ge becomes uniform.

However, in the technique described in US 2010/0059835, there is a concern that the bonding material may spread out from the bonding region or the bonding material may scatter due to the heat treatment when the bonding material by the AlGe eutectic is formed. In particular, when the AlGe eutectic scatters due to a long-time heat treatment, there is a concern that the inertial sensor may malfunction. The inertial sensor is an example of a transducer.

That is, a transducer in which the base body and the lid can be reliably bonded to each other in the bonding region and that has high reliability is demanded.

### SUMMARY

According to an aspect of the present application, there is provided a transducer including a first substrate; a second substrate; a functional element provided between the first substrate and the second substrate; and a metal eutectic layer that bonds the first substrate and the second substrate to each other in a bonding region positioned around the functional element, in which a recess is provided in a first surface of the second substrate that faces the first substrate, the recess has a second surface that is a bottom, and a side wall that connects the first surface and the second surface, the insulating layer including a first portion provided on the first surface, a second portion provided on the side wall, and a third portion provided on the second surface is provided, and the insulating layer is provided on both sides of the bonding region.

### BRIEF DESCRIPTION OF THE DRAWINGS

FIG. 1 is a plan view of a transducer according to Embodiment 1.

FIG. 2 is a sectional view of the transducer taken along line II-II in FIG. 1.

FIG. 3 is an enlarged view of portion III of FIG. 2.

FIG. 4 is an enlarged view of portion IV of FIG. 2.

FIG. 5 is a sectional view of a main portion of a base body and a lid before bonding.

FIG. 6 is a perspective view of a main portion illustrating an electrical wiring structure of a metal eutectic layer.

FIG. 7 is a flowchart illustrating a flow of a method of manufacturing the lid.

FIG. 8 is a sectional view of a main portion illustrating an aspect in a manufacturing process.

FIG. 9 is a sectional view of a main portion illustrating an aspect in a manufacturing process.

FIG. 10 is a sectional view of a main portion illustrating an aspect in the manufacturing process.

FIG. 11 is a sectional view of a main portion illustrating an aspect in the manufacturing process.

FIG. 12 is a sectional view of a main portion illustrating an aspect in the manufacturing process.

FIG. 13 is a sectional view of a main portion illustrating an aspect in the manufacturing process.

FIG. 14 is a sectional view of a main portion illustrating an aspect in the manufacturing process.

FIG. 15 is a sectional view of a main portion illustrating an aspect in the manufacturing process.

FIG. 16 is a sectional view of a main portion illustrating an aspect in the manufacturing process.

FIG. 17 is a sectional view of a bonding region according to an aspect of Embodiment 2.

FIG. 18 is a sectional view of a bonding region according to a different aspect.

FIG. 19 is a comparison table of contact resistances according to whether or not a barrier layer is provided.

FIG. 20 is a plan view of a transducer according to Embodiment 3.

FIG. 21 is an exploded perspective view of an inertial measurement device.

FIG. 22 is a perspective view of a substrate.

FIG. 23 is a perspective view of a transducer according to Embodiment 4.

FIG. 24 is a plan view of a main portion illustrating a configuration of the transducer.

FIG. 25 is a side sectional view taken along line XXV-XXV in FIG. 24.

### DESCRIPTION OF EMBODIMENTS

### Embodiment 1

### Configuration of Transducer

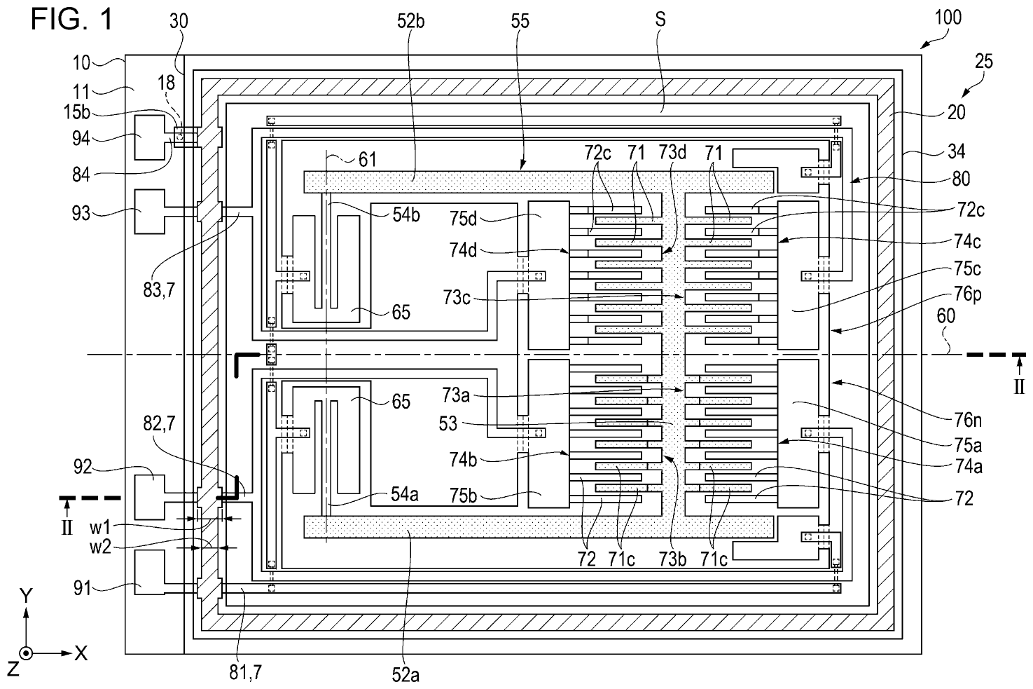

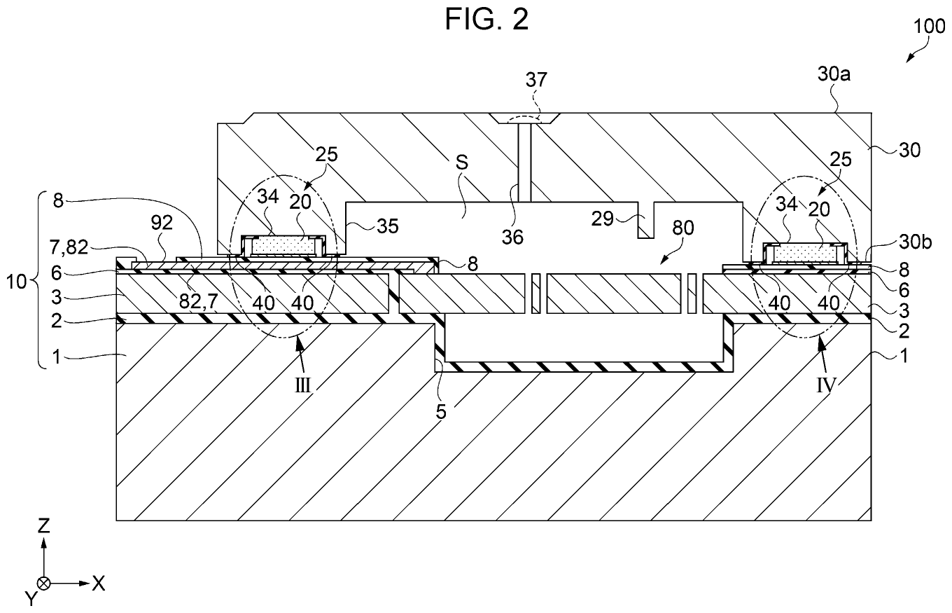

FIG. 1 is a plan view of a transducer according to Embodiment 1. FIG. 2 is a sectional view of the transducer taken along line II-II in FIG. 1.

The configuration of a transducer 100 according to the present embodiment will be described with reference to FIGS. 1 and 2.

The transducer 100 is, for example, an acceleration sensor that detects an acceleration in the vertical direction. In each drawing, an X axis, a Y axis, and a Z axis, which are three axes orthogonal to each other, are illustrated. In the present embodiment, the Z axis direction is the vertical direction, but the present disclosure is not limited thereto. A direction along the X axis is referred to as an “X direction”, a direction along the Y axis is referred to as a “Y direction”, and a direction along the Z axis is referred to as a “Z direction”. In addition, the arrow tip side in each axis direction is also referred to as a “positive side”, and the arrow base end side is also referred to as a “negative side”. For example, the Y direction refers to both the positive Y direction and the negative Y direction. In addition, the positive Z direction is also referred to as “up”, and the negative Z direction is also referred to as “down”. In addition, in each of the following drawings, the description may be made with different dimensions or scales from the actual ones in order to facilitate the description.

The transducer 100 is a one-axis acceleration sensor including a micro electro mechanical systems (MEMS) device. Generally, a transducer refers to a converter that converts a certain physical quantity into another physical quantity, and includes an electro-mechanical conversion transducer, an acoustic-electro conversion transducer, a photoelectric conversion transducer, and the like. The transducer according to an aspect of the present application may be a transducer in which the base body and the lid are bonded to each other with a bonding material, and may be an inertial sensor that converts acceleration or angular velocity into an electrical signal, a vibrator (timing device) that excites mechanical vibration by an electrical signal, and an ultrasonic sensor that converts an ultrasonic signal into an electrical signal. The transducer according to an aspect of the present application may be an RF filter, a piezoelectric mirror, a piezoelectric actuator, a pressure sensor, and the like that utilize an electromechanical coupling coefficient of a piezoelectric material.

In Embodiment 1, an acceleration sensor, which is one of the inertial sensors, is used as an example of the transducer. In an acceleration sensor in which a MEMS device element formed in a base body is sealed with a lid, when acceleration is applied as an external force, an inertial force acts on the MEMS device element, and a capacitance value in the element changes. The change in the capacitance is converted into an electrical signal by using a differential detection circuit or the like, and is extracted as a sensor signal.

As illustrated in FIG. 2, the transducer 100 includes a base body 10 as a first substrate, a functional element 80 disposed on the base body 10, a wiring layer 7 drawn from the functional element 80, a lid 30 as a second substrate that covers the functional element 80, and the like.

The base body 10 is configured by laminating a silicon on insulator (SOI) substrate configured with a substrate 1, an embedded insulating layer 2, and a semiconductor layer 3, an interlayer insulating layer 6, the wiring layer 7, and a surface insulating layer 8 in this order in the Z direction. The substrate 1 is a single crystal silicon substrate, and the embedded insulating layer 2 is provided on the upper surface of the substrate 1. SiO₂ formed by a thermal oxidation method is preferable as the embedded insulating layer 2.

The substrate 1 is provided with a substrate recess 5 recessed from the peripheral edge. The substrate recess 5 is a cavity and is a part that forms a storage space S for storing the functional element 80. A movable body 55 (FIG. 1) of the functional element 80 is configured to be swingable by the substrate recess 5. In FIG. 2, the embedded insulating layer 2 is provided on the bottom surface of the substrate recess 5, but is not necessarily provided.

The semiconductor layer 3 is, for example, a conductive silicon substrate doped with impurities such as phosphorus (P), boron (B), and arsenic (As). In the preferred example, the semiconductor layer 3 and the embedded insulating layer 2 are bonded by Si—SiO₂ SOI bonding. The bonding through an insulating film such as SiO₂ may be also referred to as direct bonding, fusion bonding, permanent bonding, and the like.

The functional element 80 is an acceleration sensor element and is formed by etching and patterning the semiconductor layer 3. In a preferred example, a deep etching technique called the Bosch process is used. The functional element 80 is fixed to the substrate 1 by a fixer 65 (FIG. 1). In the present embodiment, the functional element 80 is the acceleration sensor element, but may be another sensor element, a vibration element that constitutes a vibrator, or a piezoelectric mirror element that constitutes a piezoelectric mirror.

The lid 30 uses a silicon substrate as a preferred example. The surface of the lid 30 on the functional element 80 side is referred to as an inner surface 30b, and the surface on the side opposite to the inner surface 30b is referred to as an outer surface 30a. The inner surface 30b corresponds to a first surface. A lid recess 35 recessed from the peripheral edge is provided on the inner surface 30b of the lid 30. The lid recess 35 is a cavity and is a part that forms the storage space S for storing the functional element 80. That is, the storage space S is formed by the substrate recess 5 and the lid recess 35. The lid recess 35 is provided with a stopper 29 which is a protrusion that restricts the excessive swinging of the movable body 55 of the functional element 80. The base body 10 and the lid 30 are bonded by a metal eutectic layer 20 in a bonding region 25 provided at the peripheral edge thereof. The details of the bonding mode will be described later.

In addition, the lid 30 is provided with a sealing hole 36 passing through the lid 30. The sealing hole 36 has a role of causing the outside air and the inside of the storage space S to communicate with each other when the base body 10 and the lid 30 are bonded to each other. The sealing hole 36 is formed in a recess depressed from the outer surface 30a of the lid 30, and can be sealed with, for example, a solder ball 37 after the base body 10 and the lid 30 are bonded. Alternatively, the sealing may be performed by directly melting the lid 30 around the sealing hole 36 with laser light. By providing the sealing hole 36, outgas and moisture generated from the inside of the base body 10 or the lid 30 can be released to the outside from the sealing hole 36 when the metal eutectic layer 20 is formed. Thereafter, the sealing hole 36 is sealed with laser light, so that the inside of the storage space S can be kept in a clean atmosphere.

In a preferred example, the storage space S is filled with an inert gas such as nitrogen, helium, or argon and is airtight-sealed. It is preferable that, in a usage temperature environment of approximately −50° C. to 150° C., the storage space S is in a substantially atmospheric pressure or vacuum state. For example, when the functional element 80 is an acceleration sensor, it is preferable that the pressure in the storage space S is close to atmospheric pressure, and when the functional element 80 is an angular velocity sensor, it is preferable that the storage space S has a vacuum pressure.

### Configuration of Functional Element

As illustrated in FIG. 1, the functional element 80 is an acceleration sensor that detects acceleration in the Z direction, and employs a so-called one-sided seesaw structure in which the movable body 55 swings about a swing shaft 61.

The functional element 80 includes the fixer 65, the movable body 55 that is swingable around the swing shaft 61 along the Y axis through the center of the fixer 65, and a first rotation spring 54a and a second rotation spring 54b that couple the fixer 65 and the movable body 55, and other components. The fixer 65 is fixed to a pedestal portion (not illustrated) protruding from the substrate 1 (FIG. 2). The periphery of the pedestal portion is the substrate recess 5 (FIG. 2), and the movable body 55 is configured to be swingable. In FIG. 1, a line segment orthogonal to the swing shaft 61 and passing through the center of the functional element 80 along the X axis is set as a center line 60.

The movable body 55 includes a first bar 52a extending in the positive X direction from the first rotation spring 54a, a second bar 52b extending in the positive X direction from the second rotation spring 54b, and a third bar 53 coupling the first bar 52a and the second bar 52b.

The third bar 53 is provided with four movable electrode groups 73a to 73d having a comb shape.

The movable electrode group 73a is composed of six movable electrodes 71c extending from the third bar 53 in the positive X direction on the negative Y side of the center line 60.

The movable electrode group 73b is composed of six movable electrodes 71c extending in the negative X direction from the third bar 53 on the negative Y side of the center line 60. The number of the movable electrodes 71c is not limited to six so long as there are a plurality of movable electrodes 71c.

The movable electrode groups 73c and 73d are provided at positions that are line-symmetrical with the movable electrode groups 73a and 73b, respectively, on the positive Y side with the center line 60 as the axis of symmetry.

On the substrate 1 (FIG. 2) side, fixed electrode groups 74a to 74d facing the movable electrode groups 73a to 73d are provided.

The fixed electrode group 74a is composed of a support 75a fixed to the substrate 1 and seven fixed electrodes 72 extending from the support 75a in the negative X direction.

The fixed electrode group 74b is composed of a support 75b fixed to the substrate 1 and seven fixed electrodes 72 extending from the support 75b in the positive X direction.

The number of each of the fixed electrode groups 74a and 74b is not limited to seven, and may be the number corresponding to the number of the movable electrodes 71c. More preferably, the fixed electrode groups 74a and 74b are configured to surround three sides of the movable electrode 71c. In this way, the unnecessary electrostatic attractive force can be canceled, and the desired acceleration in the Z axis direction can be detected with high accuracy.

The fixed electrode groups 74c and 74d are provided at positions that are line-symmetrical with the fixed electrode groups 74a and 74b, respectively, on the positive Y side with the center line 60 as the axis of symmetry.

The detector using the fixed electrode group 74a and the movable electrode group 73a and the detector using the fixed electrode group 74b and the movable electrode group 73b are collectively referred to as an N-type detector 76n.

In the N-type detector 76n, a parallel flat plate type electrostatic capacitance is formed by the fixed electrode 72 and the movable electrode 71c which are disposed to face each other. The electrostatic capacitance changes in accordance with a change in the overlapping area with the fixed electrode 72 due to the displacement of the movable electrode 71c by the acceleration.

Similarly, the detector using the fixed electrode group 74c and the movable electrode group 73c and the detector using the fixed electrode group 74d and the movable electrode group 73d are collectively referred to as a P-type detector 76p. In the P-type detector 76p, a parallel flat plate type electrostatic capacitance is formed by the fixed electrode 72c and a movable electrode 71 which are disposed to face each other. The electrostatic capacitance changes in accordance with a change in the overlapping area with the fixed electrode 72c due to the displacement of the movable electrode 71 by the acceleration.

The movable electrode 71c of the N-type detector 76n has a smaller thickness in the Z direction than the movable electrode 71 of the P-type detector 76p. Specifically, the movable electrode 71c has the same thickness as the third bar 53 at the base thereof and is cut away in a stepped fashion partway in the middle of the extending direction so as to become thinner. As a result, the thickness of the 12 movable electrodes 71c on the positive Z side is reduced in the portion facing the fixed electrode 72.

The fixed electrode 72c of the P-type detector 76p has a smaller thickness in the Z direction than the fixed electrode 72 of the N-type detector 76n. Specifically, the fixed electrode 72c is, from the thickness at its base on support 75c side and the support 75d side, cut away in a stepped fashion partway in the middle of the extending direction so as to become thinner. As a result, the thickness of the 14 fixed electrodes 72c is reduced on the positive Z side in the portion facing the movable electrode 71.

With such a configuration, when acceleration is applied in the positive Z direction, the movable body 55 is displaced in the negative Z direction by an inertial force, and the overlapping area is reduced in the N-type detector 76n. On the other hand, in the P-type detector 76p, the overlapping area is maintained. In addition, when the acceleration in the negative Z direction is applied, the movable body 55 is displaced in the positive Z direction by the inertial force, the overlapping area is maintained in the N-type detector 76n, and the overlapping area is reduced in the P-type detector 76p.

Based on such a correlation, the functional element 80 can detect the acceleration in the positive/negative Z direction by differentially detecting the change in the overlapping area in the N-type detector 76n and the P-type detector 76p as the change in the electrostatic capacitance.

### Terminal Portion and Bonding Region

As illustrated in FIG. 1, the base body 10 has a substantially rectangular shape, and a short side in the negative X direction is a projecting portion 11 that projects from a short side of the lid 30. The projecting portion 11 is provided with external coupling terminals 91 to 94.

The terminal 91 is a movable electrode terminal and is electrically coupled to all the movable electrodes 71 and 71c by a wiring line 81.

The terminal 92 is an N-type fixed electrode terminal and is electrically coupled to all the fixed electrodes 72 of the N-type detector 76n by a wiring line 82.

The terminal 93 is a P-type fixed electrode terminal and is electrically coupled to all the fixed electrodes 72c of the P-type detector 76p by a wiring line 83.

The terminal 94 is a GND terminal and is electrically coupled to the metal eutectic layer 20 by a wiring line 84. The details of the coupling form between the terminal 94 and the metal eutectic layer 20 will be described later. In other words, the wiring lines 81 to 84 pass through the bonding region 25 from the outside of the bonding region 25 and are electrically coupled to the functional element 80.

The base body 10 and the lid 30 are bonded to each other by the metal eutectic layer 20 in the quadrangular annular bonding region 25 surrounding the periphery of the functional element 80. The bonding region 25 is provided along a recess 34 of the lid 30. As illustrated in FIG. 2, the recess 34 is a groove provided in the inner surface 30b of the lid 30. The recess 34 is a cavity having a rectangular shape in cross-section, and the metal eutectic layer 20 is provided in the recess 34.

As illustrated in FIG. 1, the recess 34 is provided in a quadrangular annular shape surrounding the periphery of the functional element 80 in a planar manner. The bonding region 25 is a region in which the metal eutectic layer 20 is provided in the recess 34. The metal eutectic layer 20 intersects the wiring lines 81 to 83 when viewed in plan.

In other words, the transducer 100 includes the base body 10 as the first substrate, the lid 30 as the second substrate, the functional element 80 provided between the base body 10 and the lid 30, and the metal eutectic layer 20 that bonds the base body 10 and the lid 30 to each other in the bonding region 25 positioned around the functional element 80. The recess 34 is provided in the inner surface 30b of the lid 30 as the first surface facing the base body 10.

### Details of Metal Eutectic Layer

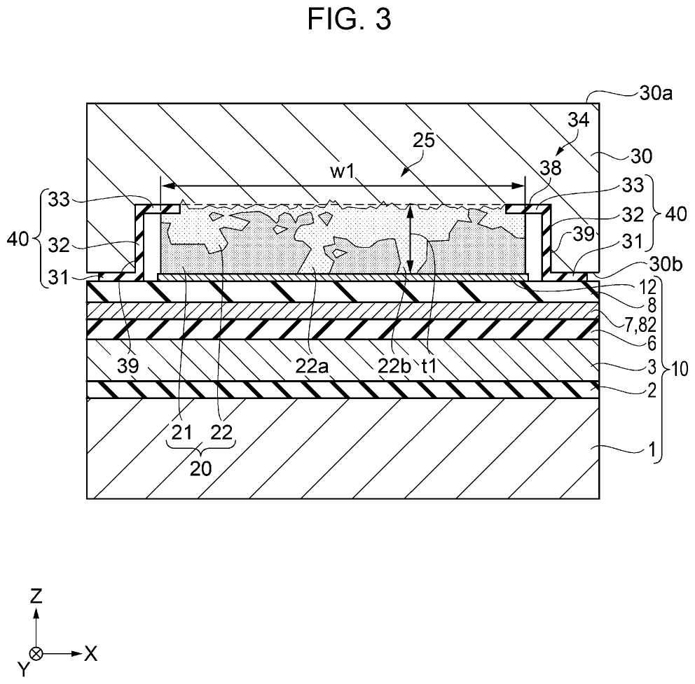

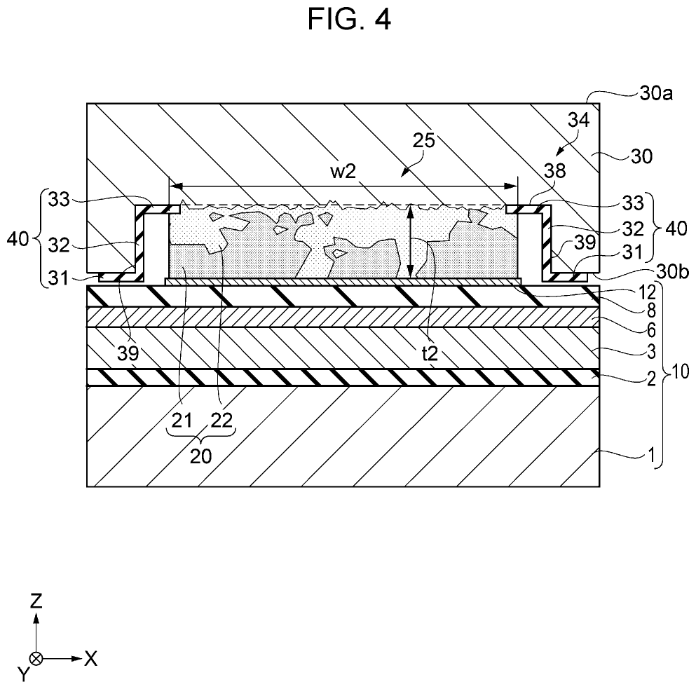

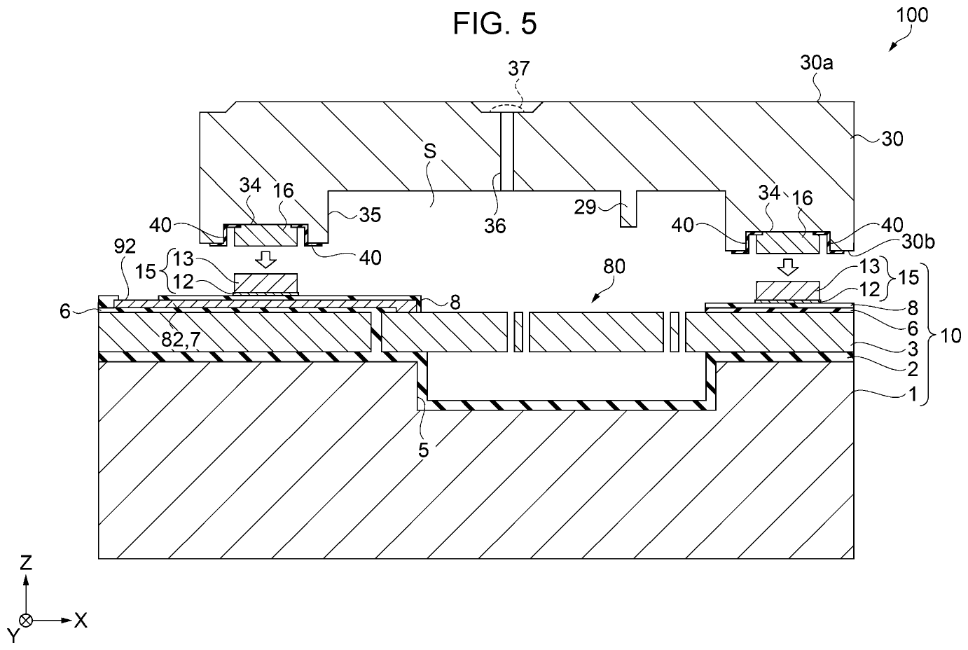

FIG. 3 is an enlarged view of portion III of FIG. 2. FIG. 4 is an enlarged view of portion IV of FIG. 2. FIG. 5 is a sectional view of a main portion of the base body and the lid before bonding.

FIG. 3 shows a cross-section of a portion where the metal eutectic layer 20 overlaps the wiring line 82 of the lower layer. The wiring line 82 is a wiring line extending from the terminal 92 to the functional element 80 side.

The base body 10 includes the substrate 1, the embedded insulating layer 2, the semiconductor layer 3, the interlayer insulating layer 6, the wiring layer 7, the surface insulating layer 8, and a barrier layer 12, which are laminated in this order from the negative Z direction. The wiring layer 7 includes the wiring line 82. In FIG. 3, the region from the substrate 1 to the barrier layer 12 is referred to as the base body 10. Furthermore, the lid 30 is bonded via the metal eutectic layer 20.

In the preferred example, the interlayer insulating layer 6 is a SiO₂ layer. In Embodiment 1, a high temperature oxide layer (HTO) formed by a high temperature CVD method is used. The interlayer insulating layer 6 may be a SiN layer. Since the surface insulating layer 8 is an upper layer of the wiring layer 7, an insulating film that can be deposited at a relatively low temperature is preferable. In Embodiment 1, a P-tetraethoxysilane (TEOS) film is stacked by a plasma chemical vapor deposition (CVD) apparatus.

The wiring layer 7 is formed of a plurality of layers and is, for example, a four-layer structure in which Ti, TiN, AlCu, and TiN are laminated in this order from the bottom. The thickness of each of the layers is 60 nm for Ti, 100 nm for TiN, 600 nm for AlCu, and 100 nm for TiN. AlCu has Al as a main component and a Cu content of 0.1% to 1.0%. The wiring layer 7 may have good conductivity and may be another metal layer.

The barrier layer 12 has a two-layer structure of Ti and TiN and is selectively provided in a portion overlapping the metal eutectic layer 20. The Ti of the barrier layer 12 is 60 nm, and the TiN of the barrier layer 12 is 100 nm. The Ti layer plays a role of enhancing the adhesion with the surface insulating layer 8, and the TiN layer plays a role of preventing Al from diffusing from AlCu. The barrier layer 12 may have an effect of preventing Al diffusion and may be another metal film such as TaN, W, or TiW. The Ti layer can be omitted when the adhesion to the surface insulating layer 8 is good.

The metal eutectic layer 20 is a eutectic layer obtained by performing eutectic bonding of a first bonding portion 15 and a second bonding portion 16 illustrated in FIG. 5 by heating and pressurizing. The eutectic generally refers to an alloy formed by solidifying a liquid phase in which two or more types of metals are mixed. Specifically, the laminated body obtained by stacking the base body 10 and the lid 30 is heated to a temperature equal to or higher than the eutectic temperature of the two metals included in the first bonding portion 15 and the second bonding portion 16 to bring the two metals into a liquid phase state, and then weight is applied to the laminated body to return the laminated body to the solid phase state by cooling, thereby bonding the laminated body. In a preferred example, the laminated body is set on the stage of the heating jig with the base body 10 below, and weight is applied for a predetermined time from the lid 30 side by a weight jig when the laminated body reaches a predetermined temperature. At this time, the weight jig is also heated. Then, once the two metals form the eutectic layer, the load is removed and cooling is performed. In the present embodiment, the metal eutectic layer 20 contains a first metal in the first bonding portion 15 and contains a second metal in the second bonding portion 16, the first metal is Al, and the second metal is Ge. The eutectic temperature of the AlGe eutectic alloy which is a eutectic of Al and Ge is substantially 420° C.

As illustrated in FIG. 5, before the metal eutectic layer 20 is formed, the first bonding portion 15 is provided on the base body 10, and the second bonding portion 16 is provided on the lid 30. The first bonding portion 15 has a two-layer structure of the barrier layer 12 and a first metal layer 13. The barrier layer 12 has a two-layer structure of Ti and TiN, and the first metal layer 13 is an AlCu layer having Al as a main component. The second bonding portion 16 is made of a single layer of the second metal layer, and the second metal layer is a Ge layer. However, Cu in the AlCu layer is mixed for the purpose of preventing electromigration, and the content is low. In the present embodiment, the content of Cu in AlCu is set to 0.1% to 1.0%. On the other hand, the main component of the second bonding portion 16 made of the second metal layer is Ge. In other words, the main component of the first bonding portion 15 is aluminum, the main component of the second bonding portion 16 is germanium, and the metal eutectic layer 20 formed of these contains aluminum and germanium.

The metal eutectic layer 20 illustrated in FIG. 3 is a faithful trace of a microscopic photograph of the eutectic layer.

As a result of the element analysis, as illustrated in FIG. 3, the metal eutectic layer 20 is formed in a state where a first region 21 in which Al, which is the first metal, is the main component and a second region 22 in which Ge, which is the second metal, is the main component are adjacent to each other. The content of the first metal in the first region 21 is higher than the content of the first metal in the second region 22. The content of the second metal in the second region 22 is higher than the content of the second metal in the first region 21.

The second region 22 extends widely along the lid 30, but a part thereof reaches the boundary with the base body 10. For example, in FIG. 3, extension portions 22a and 22b reach the base body 10. However, the extension portions 22a and 22b are stopped from diffusing by the barrier layer 12. This is because the barrier layer 12 has a function of preventing the diffusion of Al. The boundary between the first region 21 and the second region 22 is complicated and is deeply indented. The second region 22 extends at more portions than the first region 21.

The distribution of Ge in the metal eutectic layer 20 is not uniform, and the relatively large amount of Ge is present in the second region 22, and is uniform and has no concentration gradient in the region. However, Ge is uniformly present also in the first region 21 although the amount is small. The first region 21 and the second region 22 are in contact with each other without any gap, and the contact area is larger than the planar area of the bonding region 25. That is, the first region 21 and the second region 22 are randomly fitted to each other, and the bonding strength thereof is extremely high. In other words, the contact area between the first region 21 and the second region 22 is larger than the area of the bonding region 25 where the base body 10 and the lid 30 are bonded by the metal eutectic layer 20.

In general, it is known that Ge has a diamond structure and Al has a face-centered cubic lattice structure, and when the amount of Ge is large as the main component of the eutectic layer, a solid solution having a diamond structure is formed, and when the amount of Al is large as the main component, a solid solution having a face-centered cubic lattice structure is formed. The solid solution refers to a substance in which two elements are dissolved in each other and the whole is in a solid phase at a relatively uniform concentration. However, each solid solution has a different component ratio within the solid solubility limit.

That is, the second region 22 having a large amount of Ge realizes a diamond structure solid solution, and the first region 21 having a large amount of Al realizes a face-centered cubic lattice structure solid solution. The surface energy is a guide when the crystal is cut to cut out the surface, and it is known that the surface energy per unit area of Ge is higher than that of Al in any crystal plane orientation when compared between Ge and Al. In other words, the metal eutectic layer 20 includes a plurality of first regions 21 having the first metal as a main component and having a face-centered cubic lattice structure and a plurality of second regions 22 having the second metal as a main component and having a diamond structure, and the first region 21 and the second region 22 are adjacent to each other.

As illustrated in FIG. 3, a part of the second region 22 reaches the boundary with the base body 10. The second region 22 extends from the lid 30 to the base body 10. In other words, the second region 22 reaches the boundary with the base body 10. That is, the second region 22 reaches the base body 10 regardless of the distance from the lid 30. At the same time, the second region 22 having a large amount of Ge contains Al in a range not exceeding the solid solubility limit with respect to Ge. The component ratio of Ge and Al in the second region 22 is relatively uniform and does not depend on the distance from the lid 30. From the viewpoint of the surface energy, the second region 22 having a large amount of Ge reaching the boundary with the base body 10 has a high bonding strength. More preferably, it is preferable that the second region 22 having a large amount of Ge extends from the lid 30 to the base body 10 in many parts.

On the other hand, at the boundary between the lid 30 and the metal eutectic layer 20 in FIG. 3, the second bonding portion 16 made of Ge is directly deposited on the lid 30 (FIG. 5), so that Ge diffuses into the silicon which is the lid 30. That is, the second region 22 having Ge as a main component has a fine uneven shape at the boundary portion with the lid 30 (dotted line in FIG. 3), and the contact area is increased and the bonding strength is increased.

### Recess and Insulating Layer

As illustrated in FIG. 3, the metal eutectic layer 20 is provided in the recess 34.

The recess 34 is a rectangular groove provided in the inner surface 30b of the lid 30, and has a bottom surface 38 which is a bottom and side walls 39 at both ends of the bottom surface 38. The bottom surface 38 corresponds to a second surface. In other words, the recess 34 has the bottom surface 38 as the second surface and the side wall 39 that connects the inner surface 30b as the first surface and the bottom surface 38 as the second surface.

An insulating layer 40 is formed on one side wall 39 of the recess 34. The insulating layer 40 corresponds to the insulating layer according to the claims.

The insulating layer 40 has a crank shape along the recess 34 in the cross-section, and is configured with a first portion 31 provided on the inner surface 30b, a second portion 32 provided on the side wall 39, and a third portion 33 provided on the bottom surface 38. An insulating layer 40 having the same configuration is formed on the other side wall 39. The two insulating layers 40 are provided symmetrically on both sides of the metal eutectic layer 20. In FIG. 3, the first portion 31 of the insulating layer 40 is in physical contact with the surface insulating layer 8 on the base body 10 side.

In other words, the insulating layer 40 has the first portion 31 provided on the inner surface 30b as the first surface, the second portion 32 provided on the side wall 39, and the third portion 33 provided on the bottom surface 38 as the second surface. The insulating layer 40 is provided on both sides of the bonding region 25.

The material of the insulating layer 40 is a SiO₂ film in a preferred example. The material of the insulating layer 40 is not limited to the SiO₂ film, and the insulating layer 40 may be formed of a chemically stable insulating material, such as a SiN film, a B₂O₃ film, or a Bi₂O₃ film.

In other words, the insulating layer 40 is any of a silicon oxide layer, a silicon nitride layer, a boron oxide layer, and a bismuth oxide layer.

At the time of forming the metal eutectic layer 20, Al of the first bonding portion 15 and Ge of the second bonding portion 16 are heat-treated in the recess 34. Since the eutectic layer of Al and Ge changes into a liquid phase at the eutectic point, there is a possibility that the eutectic layer spreads or scatters at that time, but the insulating layer 40 on both side surfaces of the recess 34 can prevent the spreading or scattering. Specifically, since the insulating layer 40 is made of a chemically stable substance such as a SiO₂ film, the insulating layer 40 does not form a eutectic with AlGe and functions as a stopper layer.

Therefore, the eutectic layer in the liquid phase when the metal eutectic layer 20 is formed is prevented from scattering onto the functional element 80, and the metal eutectic layer 20 reliably bonds the base body 10 and the lid 30 to each other in the bonding region 25 within the recess 34.

### Differences Depending on Whether or not Metal Eutectic Layer Intersects Wiring Layer

FIG. 4 is an enlarged view of portion IV of FIG. 2 and shows a cross-section of a portion in which the wiring layer 7 is not provided in the lower layer. As illustrated in FIG. 4, in a portion in which the wiring layer 7 is not provided in the lower layer, the height of the surface insulating layer 8 on the base body 10 side is lower by the thickness of the wiring layer 7 than that in a portion in which the wiring layer 7 is provided. Therefore, the first portion 31 of the insulating layer 40 and the surface insulating layer 8 of the base body 10 are not in physical contact with each other, and a gap may be formed therebetween, but the gap is narrow in design, so that the eutectic layer in the liquid phase does not scatter to the outside of the recess 34.

On the other hand, as the volume of the recess 34, the volume of the recess 34 in a portion in which the wiring layer 7 is not provided in the lower layer in FIG. 4 is larger than the volume of the recess 34 in the portion in which the wiring layer 7 is provided in FIG. 3.

Here, when the thickness of the metal eutectic layer 20 in the recess 34 in the portion in which the wiring layer 7 is provided in FIG. 3 is set to the height t1 and the width thereof is set to w1, and the thickness of the metal eutectic layer 20 in the recess 34 in the portion in which the wiring layer 7 is not provided in FIG. 4 is set to the height t2 and the width thereof is set to w2, t1<t2 and w1>w2 are established. This is because the width of the eutectic layer in the liquid phase formed during the formation of the metal eutectic layer 20 is automatically adjusted to the optimum width according to the distance between the bottom surface 38 of the recess 34 and the surface insulating layer 8 on the base body 10 side.

As a result, in plan view of FIG. 1, the width of the metal eutectic layer 20 is a wide width w1 at only the portion intersecting the wiring lines 81 to 84, and is a width w2 at the other portions.

In other words, the width of the metal eutectic layer 20 in the portion overlapping the wiring line is larger than the other portion, and the height of the metal eutectic layer 20 in the portion overlapping the wiring line is lower than the other portion.

The description returns to FIG. 3.

The width of the recess 34 in the example is 90 to 100 μm, and the depth of the recess 34 is 0.1 to 0.5 μm. At this time, the width of the metal eutectic layer 20 is 60 μm or less. This is an example, and the setting may be appropriately made according to the size and specifications of the device.

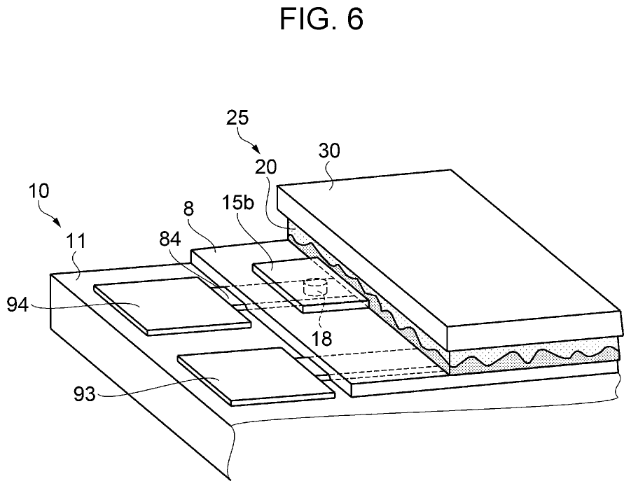

FIG. 6 is a perspective view of a main portion illustrating an electrical wiring structure of the metal eutectic layer, and is an enlarged perspective view of the vicinity of the terminal 94 in FIG. 1.

As illustrated in FIG. 6, the metal eutectic layer 20 is electrically coupled to the terminal 94, which is a GND terminal, by a protrusion portion 15b of the first bonding portion 15 (FIG. 5). The protrusion portion 15b is a wiring pattern formed together with the first bonding portion 15, and projects from the bonding region 25 toward the terminal 94. Since the protrusion portion 15b does not have the facing portion on the second bonding portion 16 (FIG. 5) side, the protrusion portion 15b functions as an electrical wiring line drawn from the metal eutectic layer 20.

The protrusion portion 15b is provided to overlap the wiring line 84 coupled to the terminal 94 via the surface insulating layer 8. A conductive contact portion 18 is provided in a portion where the wiring line 84 and the protrusion portion 15b overlap each other in the surface insulating layer 8.

As a result, the terminal 94 and the metal eutectic layer 20 are electrically coupled via the wiring line 84, the contact portion 18, and the protrusion portion 15b. The potential is not limited to the GND potential, and may be any electrically stable potential, for example, a constant potential including a power supply potential. In other words, the lid 30 is electrically coupled to any of the plurality of electrical wiring lines provided in or on the base body 10 via the metal eutectic layer 20.

### Manufacturing Method of Lid

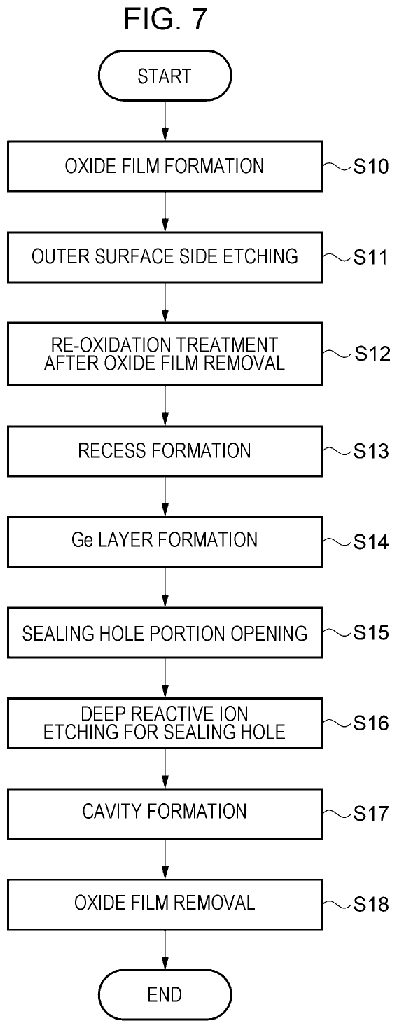

FIG. 7 is a flowchart diagram illustrating a flow of a method of manufacturing a lid. FIGS. 8 to 16 are sectional views of the main portions illustrating an aspect in the manufacturing process.

Here, a method of manufacturing the lid 30 including the recess 34 including the insulating layer 40 will be described with reference to FIG. 7 as a main part, as appropriate, with reference to other drawings.

In step S10, a silicon substrate 30s is prepared, and both surfaces of the silicon substrate 30s are coated with oxide films. This state is illustrated in FIG. 8, and at this time, an oxide film 64 on the inner surface 30b side is formed to be thicker than an oxide film 63 on the outer surface 30a side. Specifically, after both surfaces are coated by thermal oxidation with oxide films, the P-TEOS film is laminated on the inner surface 30b by the plasma CVD apparatus to make the oxide film 64 thick, and the film thickness is made asymmetrical between the front and back. In FIGS. 8 to 16, the inner surface 30b side of the lid 30 is illustrated above.

In step S11, patterning is performed on the outer surface 30a side of the silicon substrate 30s by a photolithography method, and the oxide film 63 of the sealing hole forming portion or the like is selectively removed. Next, silicon is etched by anisotropic etching. This state is illustrated in FIG. 9. The patterning in the following description refers to a method using a photolithography method.

In step S12, after the oxide films 63 and 64 on both surfaces of the silicon substrate 30s are removed, oxide films 66 and 67 are formed by performing an oxidation treatment again on both surfaces of the silicon substrate 30s, as illustrated in FIG. 10. In a preferred example, the wet oxidation treatment is performed to secure a thermal oxide film thickness that can withstand the subsequent Bosch process.

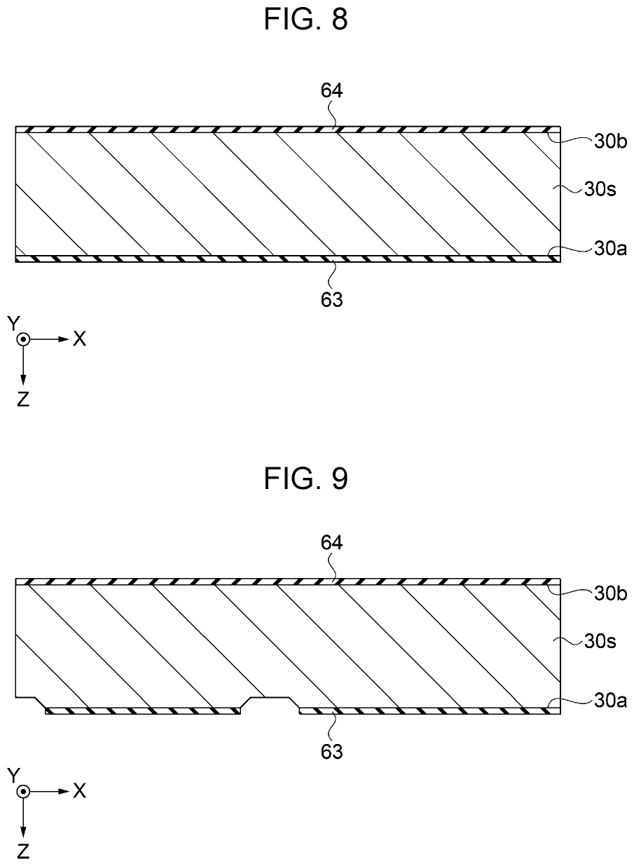

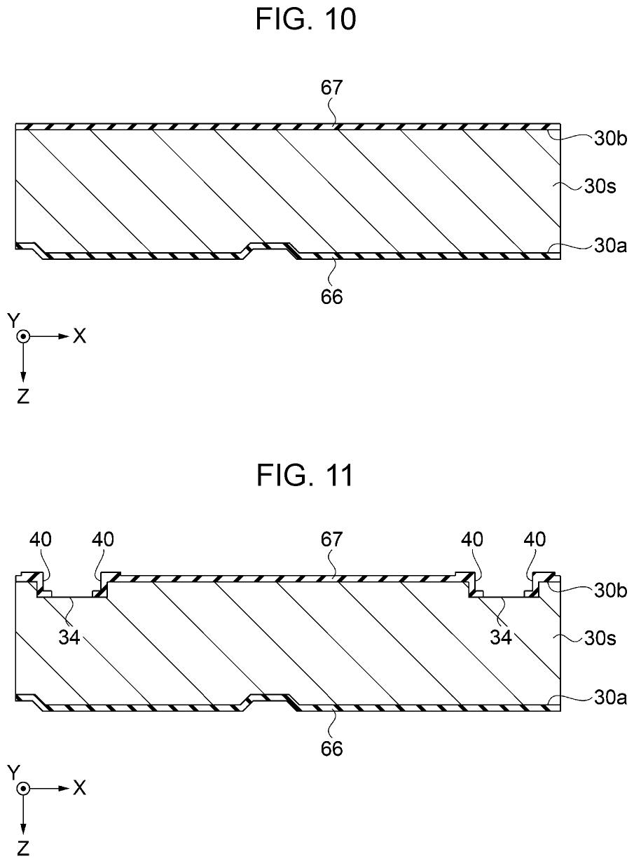

In step S13, the recess 34 is provided on the inner surface 30b side of the silicon substrate 30s. Specifically, the portion of the oxide film 67 in which the recess 34 is to be formed is patterned, the oxide film 67 and the silicon surface are etched, and the recess 34 is formed. Subsequently, the P-TEOS film is stacked by the plasma CVD apparatus, and then patterning is performed to selectively form the insulating layer 40 around the side wall of the recess 34. This state is illustrated in FIG. 11.

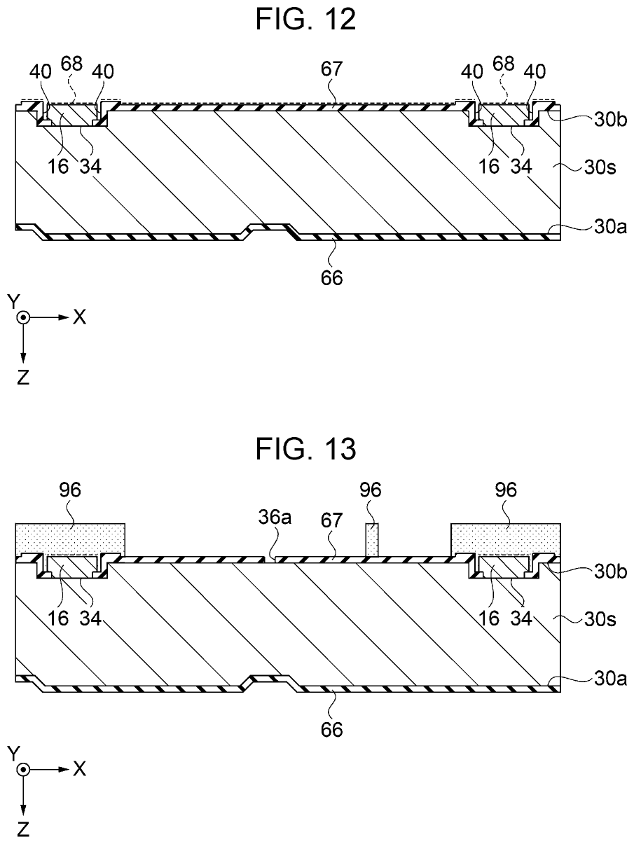

In step S14, after a Ge layer is provided on the entire inner surface 30b side of the silicon substrate 30s by a sputtering method, patterning is performed to form the second bonding portion 16 in the recess 34. This state is illustrated in FIG. 12. In the preferred example, a protective film 68 made of a P-TEOS film is provided on the entire inner surface 30b side including the second bonding portion 16. The protective film 68 protects the second bonding portion 16 in a later cavity forming step.

In step S15, an opening 36a that is the starting point of the sealing hole is formed in the oxide film 67 on the inner surface 30b side. Specifically, as illustrated in FIG. 13, a stepper exposure apparatus forms the opening 36a in the oxide film 67. Subsequently, as illustrated in FIG. 13, resist 96 is provided on the remaining portion including the recess 34 and the stopper 29 (FIG. 5).

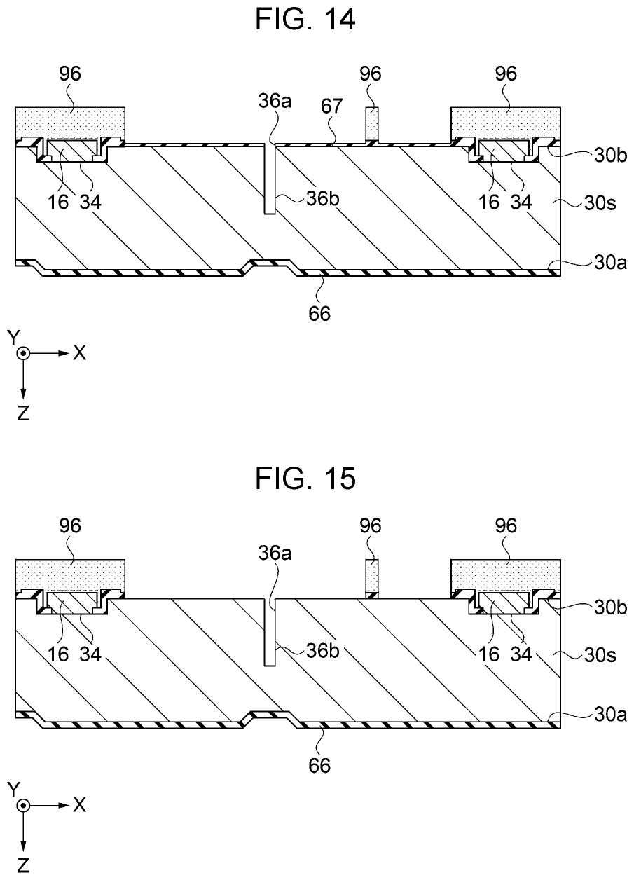

In step S16, primary deep reactive ion etching using a Bosch process is performed on the inner surface 30b side. This state is illustrated in FIG. 14, and a sealing hole 36b is processed to the primary depth from the opening 36a. In addition, the oxide film 67 is made thin.

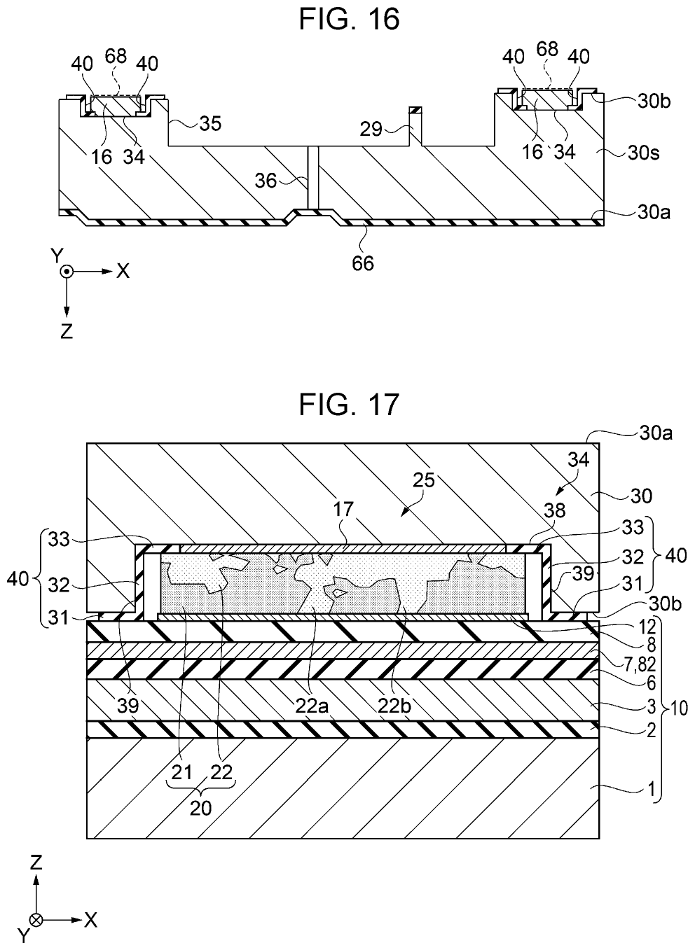

In step S17, the lid recess 35, which is a cavity in the lid 30, is formed. First, as illustrated in FIG. 15, the oxide film 67 on the inner surface 30b side is removed to expose the surface of the silicon substrate 30s of the portion that becomes the cavity. Next, secondary deep reactive ion etching is performed using a Bosch process. This state is illustrated in FIG. 16, the lid recess 35 is formed, and the sealing hole 36 passes through the silicon substrate 30s. At this time, the protective film 68 remains on the surface of the second bonding portion 16.

In step S18, all the oxide films are removed by wet etching using buffered hydrogen fluoride (BHF). As a result, the lid 30 illustrated in FIG. 5 is formed.

As described above, according to the transducer 100 of the present embodiment, the following effects can be obtained.

The transducer 100 includes the base body 10 as the first substrate, the lid 30 as the second substrate, the functional element 80 provided between the base body 10 and the lid 30, the metal eutectic layer 20 that bonds the base body 10 and the lid 30 to each other in the bonding region 25 positioned around the functional element 80, and the recess 34 provided in the inner surface 30b as the first surface facing the base body 10 in the lid 30, in which the recess 34 has the bottom surface 38 as the second surface and the side wall 39 that connects the inner surface 30b as the first surface and the bottom surface 38 as the second surface, and the insulating layer 40 having the first portion 31 provided on the inner surface 30b as the first surface, the second portion 32 provided on the side wall 39, and the third portion 33 provided on the bottom surface 38 as the second surface is provided, and the insulating layer 40 is provided on both sides of the bonding region 25.

As a result, the base body 10 and the lid 30 can be reliably bonded to each other by the metal eutectic layer 20 in the bonding region 25. Specifically, when the metal eutectic layer 20 is formed, the Al of the first bonding portion 15 and the Ge of the second bonding portion 16 are heat-treated in the recess 34. Since the eutectic layer of Al and Ge changes into a liquid phase at the eutectic point, there is a possibility that the eutectic layer spreads or scatters at that time, but the insulating layer 40 on both side surfaces of the recess 34 can prevent the spreading or scattering. This is because the insulating layer 40 is made of a chemically stable substance such as a SiO₂ film, and thus, the eutectic reaction does not proceed between the insulating layer 40 and AlGe, and thus, the insulating layer 40 functions as a stopper layer. Therefore, the eutectic layer in the liquid phase when the metal eutectic layer 20 is formed is prevented from scattering onto the functional element 80, and the metal eutectic layer 20 reliably bonds the base body 10 and the lid 30 to each other in the bonding region 25 within the recess 34.

Therefore, the transducer 100 in which the base body 10 and the lid 30 can be reliably bonded to each other in the bonding region 25 and that has high reliability can be provided.

In addition, the metal eutectic layer 20 contains aluminum and germanium, and the insulating layer 40 is any of a silicon oxide layer, a silicon nitride layer, a boron oxide layer, and a bismuth oxide layer.

As a result, since the insulating layer 40 is made of a chemically stable substance, the eutectic reaction does not proceed between the insulating layer 40 and AlGe, and the insulating layer 40 can function as a stopper layer.

In addition, the width of the metal eutectic layer 20 in the portion overlapping the wiring line is larger than the other portion.

Accordingly, at the time of forming the metal eutectic layer 20, the eutectic layer in the liquid phase naturally spreads according to the distance between the bottom surface 38 of the recess 34 and the surface insulating layer 8 on the base body 10 side and is adjusted to the optimum width, so that the base body 10 and the lid 30 can be reliably bonded to each other.

In addition, the height of the metal eutectic layer 20 in the portion overlapping the wiring line is lower than the other portion.

Accordingly, at the time of forming the metal eutectic layer 20, the eutectic layer in the liquid phase naturally spreads according to the distance between the bottom surface 38 of the recess 34 and the surface insulating layer 8 on the base body 10 side and is adjusted to the optimum height, so that the base body 10 and the lid 30 can be reliably bonded to each other.

### Embodiment 2

### Different Aspect of Bonding Region

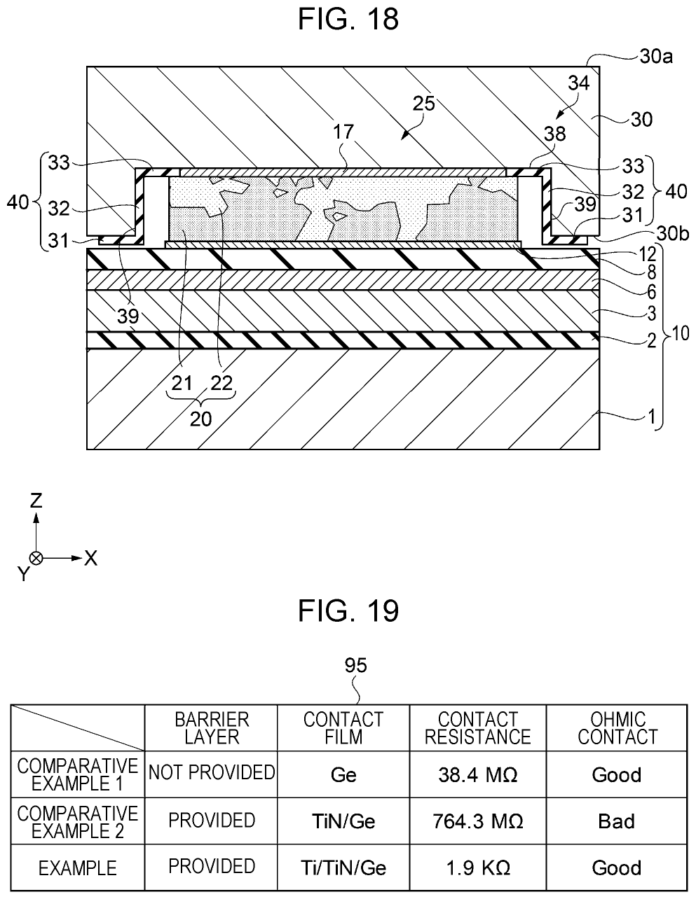

FIG. 17 is a sectional view of a bonding region according to an aspect of Embodiment 2 and corresponds to FIG. 3. FIG. 18 is a sectional view of a bonding region according to a different aspect and corresponds to FIG. 4.

In the above embodiment, the second bonding portion 16 is directly deposited on the lid 30. However, the present disclosure is not limited thereto, and a barrier layer 17 may be provided on the base. Hereinafter, the same parts as those in the above embodiment will be given the same reference numerals, and the description thereof will be omitted.

In the present embodiment, the barrier layer 17 is provided between the lid 30 and the second bonding portion 16 (FIG. 5). Other than this point, the configuration is the same as that of the above embodiment.

The barrier layer 17 has a two-layer structure of Ti and TiN and is selectively provided in a portion overlapping the metal eutectic layer 20, similarly to the barrier layer 12. The barrier layer 17 is stacked in order of Ti and TiN from the lid 30 side.

FIG. 17 shows a cross-section of a portion where the metal eutectic layer 20 overlaps the wiring line 82 in the lower layer. Therefore, the first portion 31 of the insulating layer 40 is in physical contact with the surface insulating layer 8 on the base body 10 side, as in FIG. 3. On the other hand, in FIG. 18, as in FIG. 4, the first portion 31 of the insulating layer 40 is not in physical contact with the surface insulating layer 8 on the base body 10 side.

As illustrated in FIG. 17, the metal eutectic layer 20 is formed in a state where the first region 21 in which Al, which is the first metal, is the main component and the second region 22 in which Ge, which is the second metal, is the main component are adjacent to each other. The second region 22 extends widely along the lid 30, but a part thereof reaches the boundary with the base body 10. That is, as described above with reference to FIG. 3, a bonding having a high bonding strength is realized by the metal eutectic layer 20.

FIG. 19 is a comparison table of contact resistances according to whether or not a barrier layer is provided.

Further, by providing the barrier layer 17, the diffusion of Ge into the lid 30 is prevented and the electrical contact with the silicon constituting the lid 30 is improved. That is, the barrier layer 17 can realize ohmic contact between the metal eutectic layer 20 and the lid 30.

Table 95 of FIG. 19 shows the experimental results according to the inventors, and when the second bonding portion 16 was directly deposited on the lid 30 as in Comparative Example 1 of Table 95, although Si and Ge were in ohmic contact, the contact resistance value thereof was a relatively large value of substantially 38.4 MΩ. The contact resistance value is a resistance value at one contact of the same size.

On the other hand, as shown in Example of Table 95, when the barrier layer 17 of Ti/TiN was provided, the contact resistance value was substantially 1.9 KΩ, which was a small value in the ohmic contact. From this result, it is found that better electrical conduction can be obtained by providing the barrier layer 17 of Ti/TiN between the lid 30 and the metal eutectic layer 20. The same applies to the portion illustrated in FIG. 18 in which the wiring line is not provided in the lower layer of the metal eutectic layer 20.

On the other hand, as shown in Comparative Example 2 of Table 95, when a single TiN layer of the barrier layer 17 was provided, an ohmic contact was not obtained, and the contact resistance value was also a value larger than that of Comparative Example 1.

In addition, in the above description, although pure Ge not containing impurities is used for Ge of the second bonding portion 16, according to the experimental result by the inventors, when the barrier layer 17 of Ti/TiN is provided, it is confirmed that even when P-type Ge containing impurities such as Ga is used instead of pure Ge, the ohmic contact is obtained and the contact resistance value is substantially 62.3 KΩ, which is a small value. Therefore, P-type Ge may be used for the second bonding portion 16.

As described above, according to the transducer 100 of the present embodiment, the following effects can be obtained in addition to the effects in the above embodiment.

The transducer 100 includes the Ti/TiN barrier layer 17 between the lid 30 and the metal eutectic layer 20.

Therefore, the potential can be favorably supplied to the lid.

Therefore, the transducer 100 in which the base body 10 and the lid 30 can be reliably bonded to each other in the bonding region 25 and that has higher reliability can be provided.

### Embodiment 3

### Application to Inertial Measurement Device

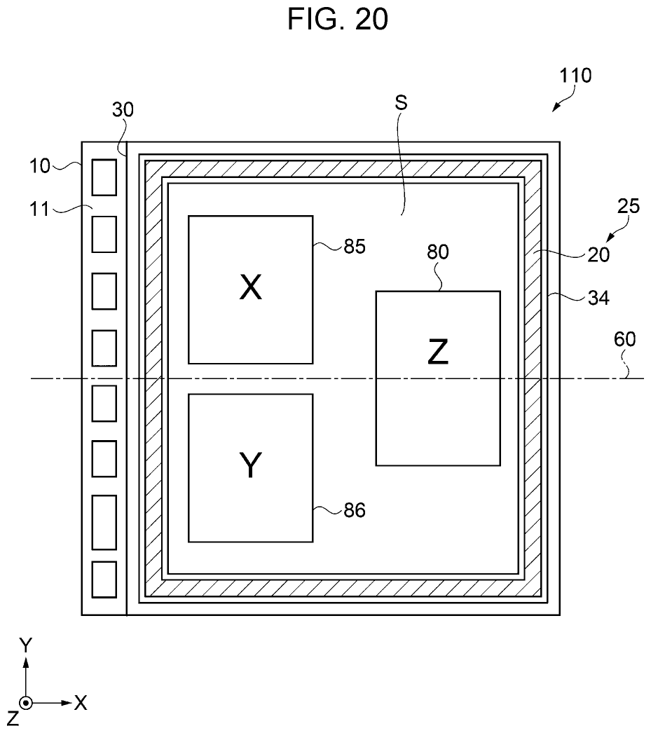

FIG. 20 is a plan view of a transducer according to Embodiment 3 and corresponds to FIG. 1.

In the above embodiments, the transducer 100 is described as storing one functional element 80, but the configuration of the transducer is not limited thereto, and a plurality of functional elements may be stored. Hereinafter, the same parts as those in the above embodiments will be given the same reference numerals, and the description thereof will be omitted.

As illustrated in FIG. 20, a transducer 110 of the present embodiment includes a functional element 85 and a functional element 86 in addition to the functional element 80 described above.

The functional element 85 is an electrostatic capacitance-change type acceleration sensor that detects acceleration in the X direction. The functional element 86 is an electrostatic capacitance-change type acceleration sensor that detects an acceleration in the Y direction. That is, the transducer 110 is a three-axis acceleration sensor that can detect acceleration in the three axes in the XYZ direction. As in FIG. 1, the base body 10 has a substantially rectangular shape and is provided with the projecting portion 11 projecting from the lid 30 on the long side in the negative X direction. The projecting portion 11 is provided with a plurality of external coupling terminals.

The transducer 110 has the same configuration as the transducer 100, in which the base body 10 and the lid 30 are bonded to each other by the metal eutectic layer 20 in the bonding region 25, and the lid 30 is provided with the recess 34. The bonding region 25 is formed in the recess 34 in a planar manner. The region inside the bonding region 25 is the storage space S.

The three functional elements 80, 85, and 86 are stored in the storage space S in a state where the detection swing is possible. In FIG. 20, the bonding region 25 is a region of a quadrangular ring smaller than the outer peripheral edge of the lid 30, but the shape of the bonding region 25 is not limited thereto. The bonding region 25 may be a polygon or an ellipse as long as the bonding region 25 is closed to surround the functional elements 80, 85, and 86. However, the pull-out wiring line (not illustrated) is configured to intersect the bonding region 25 when viewed in plan.

As described above, according to the transducer 110 of the present embodiment, in addition to the effects in the above embodiments, the following effects can be obtained.

In the transducer 110, as in the transducer 100, the base body 10 and the lid 30 are bonded to each other by the metal eutectic layer 20 in the bonding region 25, and the bonding region 25 is formed in the recess 34 of the lid 30 in a planar manner.

Therefore, the transducer 110 in which the base body 10 and the lid 30 can be reliably bonded to each other in the bonding region 25 and that has high reliability can be provided.

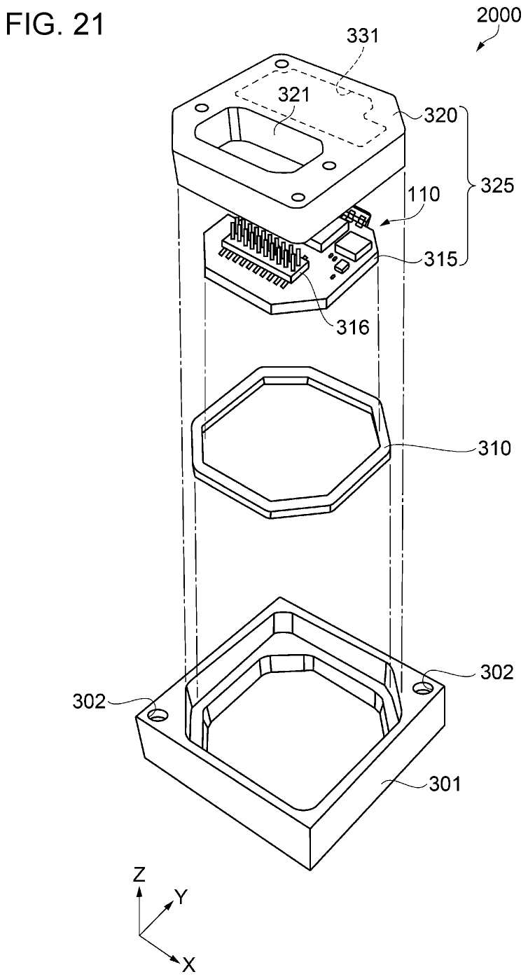

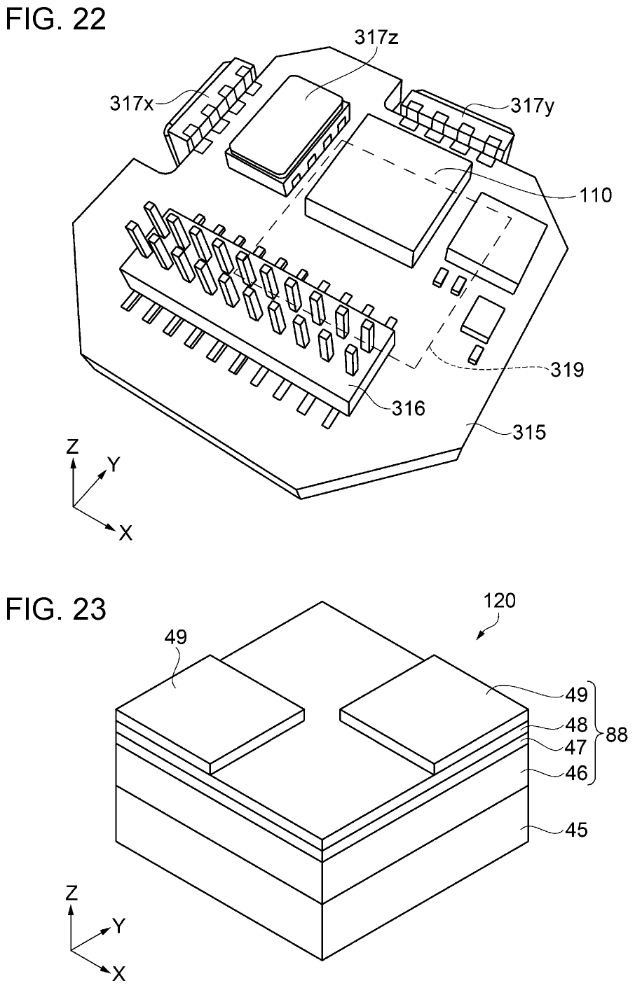

FIG. 21 is an exploded perspective view of an inertial measurement device. FIG. 22 is a perspective view of a substrate.

As illustrated in FIG. 21, the transducer 110 is mounted on an inertial measurement device 2000 of the present embodiment. The inertial measurement device 2000 is a rectangular parallelepiped having a substantially square planar shape.

The inertial measurement device 2000 is an inertial measurement unit (IMU) that detects the posture and the behavior of mounted bodies such as an automobile or a robot. The inertial measurement device 2000 functions as a so-called six-axis motion sensor including a three-axis acceleration sensor and a three-axis angular velocity sensor.

The inertial measurement device 2000 includes an outer case 301, a bonding member 310, and a sensor module 325 in which the transducer 110 is mounted.

The outer shape of the outer case 301 is the same as the overall shape of the inertial measurement device 2000, and is a rectangular parallelepiped having a substantially square planar shape. Screw holes 302 are formed at two locations near the vertices located in the diagonal direction of the square. The inertial measurement device 2000 can be fixed to a mounted surface of the mounted body such as an automobile by allowing two screws to pass through the two screw holes 302.

Further, the outer case 301 is box-shaped, and the sensor module 325 is stored inside the outer case 301. Specifically, the sensor module 325 is inserted into the outer case 301 with the bonding member 310 interposed therebetween.

The sensor module 325 includes an inner case 320 and a substrate 315.

The inner case 320 is a member that supports the substrate 315, and the substrate 315 is bonded to the lower surface of the inner case 320 via an adhesive.

Further, the inner case 320 has a shape that is stored inside the outer case 301. The inner case 320 is formed with an inner case recess 331 for preventing contact with the substrate 315 and an opening 321 for exposing a connector 316 to be described later. The inner case 320 is bonded to the outer case 301 via the bonding member 310.

Next, the substrate 315 on which the transducer 110 is mounted will be described.

As illustrated in FIG. 22, the transducer 110, the connector 316, an angular velocity sensor 317z that detects angular velocity around the Z axis, and the like are mounted on the surface of the inner case 320 side, which is the upper surface of the substrate 315. An angular velocity sensor 317x that detects angular velocity around the X axis and an angular velocity sensor 317y that detects angular velocity around the Y axis are mounted on the side surfaces of the substrate 315. The transducer 100 may be mounted instead of the transducer 110.

In addition, a control IC 319 is mounted, as a controller, on a surface of the outer case 301 side, which is a lower surface of the substrate 315. The control IC 319 is a micro controller unit (MCU), includes a storage including a non-volatile memory, an A/D converter, and the like, and controls each portion of the inertial measurement device 2000. The storage stores a program that defines an order and content for detecting acceleration and angular velocity, a program that digitizes detected data and incorporates the detected data into packet data, accompanying data, and the like. In addition, a plurality of electronic components are mounted on the substrate 315.

According to the inertial measurement device 2000, since the transducer 110 is used, the inertial measurement device 2000 having excellent long-term reliability and achieving the effects according to the above embodiments can be provided.

### Embodiment 4

### Application to Timing Device

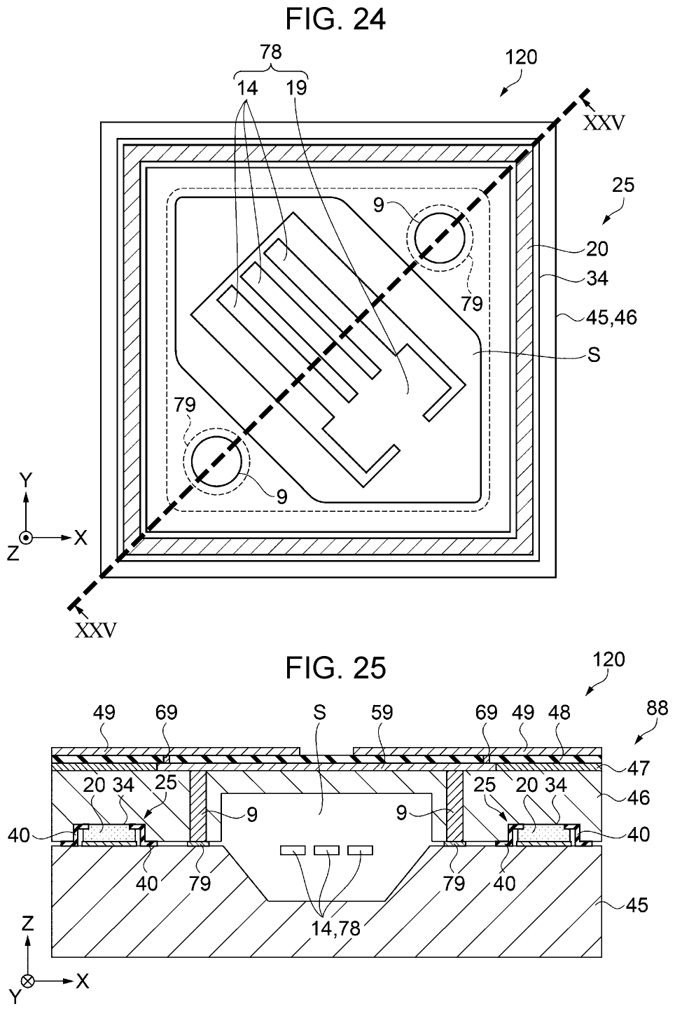

FIG. 23 is a perspective view of a transducer according to Embodiment 4. FIG. 24 is a plan view of a main portion illustrating a configuration of the transducer. FIG. 25 is a side sectional view taken along line XXV-XXV in FIG. 24.

In the above embodiments, the transducers 100 and 110 are described, but the present disclosure is not limited thereto, and may be applied to a timing device such as a vibrator or an oscillator as a transducer. Hereinafter, the same parts as those in the above embodiments will be given the same reference numerals, and the description thereof will be omitted.

A transducer 120 of the present embodiment illustrated in FIG. 23 is an oscillator. The transducer 120 includes a functional element 78. The functional element 78 is a vibration element made of a MEMS device (FIG. 24).

As illustrated in FIG. 23, the transducer 120 has a flat rectangular parallelepiped shape, and is configured to include a first substrate 45, a lid 88, and the like. In each drawing, the stacking direction of the lid 88 with respect to the first substrate 45 is set as the positive Z direction.

The first substrate 45 is a base substrate made of an SOI substrate. As illustrated in FIG. 24, the functional element 78 formed integrally with the substrate is provided at a substantial center of the first substrate 45. The functional element 78 includes a base 19 supported by the first substrate 45 and a movable portion 14 extending from the base 19. A pair of excitation electrodes (not illustrated) are provided on the functional element 78. In FIG. 24, the number of the movable portions 14 is three, but the number of the movable portions 14 is not limited to this. In this manner, the functional element 78 of the present embodiment is a silicon vibration element. The functional element 78 is not limited to the silicon vibration element, and may be a vibration element such as a crystal vibration element or a ceramic vibration element.

As illustrated in FIG. 23, the lid 88 has a substantially square shape when viewed in plan, and is configured to include a second substrate 46, a circuit layer 47, an interlayer insulating layer 48, an external electrode 49, and the like.

The second substrate 46 is made of a silicon substrate, and in the positive Z direction, the second substrate 46 includes the circuit layer 47, the interlayer insulating layer 48, and the external electrode 49 in this order.

The circuit layer 47 is a circuit layer formed by a semiconductor process on one surface of the second substrate 46, and an oscillation circuit 59 (FIG. 25) is formed in the circuit layer 47. The oscillation circuit 59 is formed of an integrated circuit including an active element such as a transistor and a passive element such as a capacitor or a resistor. The oscillation circuit 59 is an oscillation circuit that causes the functional element 78 to oscillate to generate an output signal having a predetermined frequency. In the present embodiment, the transducer 120 is an oscillator including an oscillation circuit, but the present disclosure is not limited thereto, and the transducer 120 does not necessarily include an oscillation circuit. Therefore, the transducer 120 may be a vibrator or another timing device.

In the preferred example, the interlayer insulating layer 48 is a SiO₂ layer.

The external electrode 49 is a rectangular mounting terminal, and a pair of the external electrodes 49 are provided at diagonal portions of the lid 88. That is, when the transducer 120 is mounted, the transducer 120 is surface-mounted with the lid 88 side facing the mounting surface of, for example, the substrate.

As illustrated in FIG. 24, the transducer 120 has the same configuration as the transducer 100, in which the first substrate 45 and the second substrate 46 (lid 88) are bonded to each other by the metal eutectic layer 20 in the bonding region 25, and the second substrate 46 is provided with the recess 34. The recess 34 is provided in a quadrangular annular shape at the peripheral edge portion of the second substrate 46. The bonding region 25 is formed in the recess 34 in a planar manner. The storage space S is provided inside the bonding region 25.

As illustrated in FIG. 25, the storage space S is a space in which the cavity in the first substrate 45 and the cavity in the second substrate 46 are formed to overlap each other, and the functional element 78 is provided to be swingable in the storage space S.

A through electrode 9 is provided between the bonding region 25 and the storage space S. The through electrode 9 is a through electrode provided in a contact hole passing through the second substrate 46, and electrically couples the excitation electrode of the functional element 78 and the oscillation circuit 59. In the present embodiment, a pair of through electrodes 9 are provided at positions overlapping the external electrodes 49.

One end of the through electrode 9 is electrically coupled to the oscillation circuit 59, and the other end is electrically coupled to a coupling terminal 79 of the second substrate 46. The coupling terminal 79 is electrically coupled to one of the excitation electrodes of the functional element 78 by a wiring line (not illustrated). Similarly, the other excitation electrode of the functional element 78 is also electrically coupled to the oscillation circuit 59 via the corresponding through electrode 9.

The oscillation circuit 59 and one of the external electrodes 49 are electrically coupled to each other by a contact electrode 69. The other external electrode 49 is also electrically coupled to the oscillation circuit 59 by the contact electrode 69.

The configuration of the recess 34 including the insulating layer 40 and the metal eutectic layer 20 is the same as that described in the above embodiments. In FIG. 24, there is no wiring line that intersects the metal eutectic layer 20, but a wiring line that intersects the metal eutectic layer 20 may be provided as in the above-described embodiments.

As described above, according to the transducer 120 of the present embodiment, in addition to the effects in the above embodiments, the following effects can be obtained.

The transducer 120 is the same as the transducer 100, and the first substrate 45 and the second substrate 46 are bonded to each other by the metal eutectic layer 20 in the bonding region 25, and the bonding region 25 is formed in the recess 34 of the lid 88 in a planar manner.

Therefore, the transducer 120 in which the first substrate 45 and the second substrate 46 can be reliably bonded to each other in the bonding region 25 and that has high reliability can be provided.

What is claimed is:

1. A transducer comprising, when three axes orthogonal to each other are set as an X axis, a Y axis, and a Z axis:
a first substrate;
a second substrate that is disposed to overlap the first substrate in a Z axis direction along the Z axis and is provided with an insulating layer on a surface of the second substrate;
a functional element provided between the first substrate and the second substrate; and
a metal eutectic layer that bonds the first substrate and the second substrate to each other in a bonding region positioned around the functional element, wherein
a recess is provided in a first surface of the second substrate on the first substrate side,
the recess is configured with
a second surface that is a bottom, and
a side wall that connects the first surface and the second surface,
the insulating layer includes
a first portion provided on the first surface,
a second portion provided on the side wall, and
a third portion provided on the second surface, and
the bonding region is disposed between second portions, each of which is the second portion of the insulating layer, when viewed in plan in a Y axis direction along the Y axis.

2. The transducer according to claim 1, wherein the metal eutectic layer contains
a first metal and
a second metal, and
the insulating layer is
any one of a silicon oxide layer, a silicon nitride layer, a boron oxide layer, and a bismuth oxide layer.

3. The transducer according to claim 2, further comprising, when viewed in plan from the Z axis direction:
a wiring line that extends from an outside of the second substrate, intersects the bonding region, and is electrically coupled to the functional element, wherein,
when a width of a portion of the metal eutectic layer that overlaps the wiring line is denoted by w1, and
a width of a portion of the metal eutectic layer that does not overlap the wiring line is denoted by w2,
$$w 1 > w 2$$
is satisfied.

4. The transducer according to claim 3, wherein, when a height of a portion of the metal eutectic layer that overlaps the wiring line is denoted by t1, and
a height of a portion of the metal eutectic layer that does not overlap the wiring line is denoted by t2,
$$t 1 < t 2$$
is satisfied.

5. The transducer according to claim 2, wherein the first metal has aluminum as a main component, and
the second metal has germanium as a main component.
